(19) United States
(12) Patent Application Publication
(10) Pub. No.: US 2021/0067156 A1
(43) Pub. Date: Mar. 4, 2021

(54) GATE DRIVER CIRCUITRY

(71) Applicants: Kabushiki Kaisha Toshiba, Tokyo (JP); Toshiba Electronic Devices & Storage Corporation, Tokyo (JP)

(72) Inventor: Yukio Tsunetsugu, Yokohama Kanagawa (JP)

(21) Appl. No.: 16/784,325

(22) Filed: Feb. 7, 2020

(30) Foreign Application Priority Data
Aug. 26, 2019 (JP) 2019-153989
Nov. 8, 2019 (JP) 2019-203445

(51) Int. Cl. H03K 17/687; H03K 17/693

(52) U.S. Cl. CPC H03K 17/6872; H03K 17/693

(57) ABSTRACT

A gate driver circuitry includes a first driver circuitry including an n-type first transistor, a p-type second transistor, a level-up circuitry, and a level-down circuitry. The second transistor has a drain connected to a drain of the first transistor, and operates at a reference voltage higher than that of the first transistor. The level-up circuitry shifts a voltage applied to the gate of the first transistor to a high-level voltage, and makes the voltage to be fed back to the gate of the second transistor. The level-down circuitry shifts a voltage applied to the gate of the second transistor to a low-level voltage, and makes the voltage to be fed back to the gate of the first transistor. The first driver circuitry outputs a drive voltage of a first power transistor from the drains of the first transistor and the second transistor.

### CROSS REFERENCE TO THE RELATED APPLICATIONS

This application is based upon and claims the benefit of priority from the prior Japanese Patent Application No. 2019-153989, filed on Aug. 26, 2019, and the prior Japanese Patent Application No. 2019-203445, filed on Nov. 8, 2019, the entire contents of which are incorporated herein by reference.

### FIELD

The embodiments of the present invention relate to a gate driver circuitry.

### BACKGROUND

As a power semiconductor element which switches a high current, a power MOSFET (Metal-Oxide-Semiconductor Field-Effect-Transistor) is widely used. The power MOSFET has a structure of DMOS (Double-Diffused MOSFET) as one example, and it performs switching by applying voltages to gates of an N-channel DMOS and a P-channel DMOS (which are described as NDMOS and PDMOS, respectively, hereinafter), for example. As circuitries which apply the voltages to the gates of the NDMOS and the PDMOS which are externally provided, a CMOS (Complementary MOS) for the NDMOS and a CMOS for the PDMOS are sometimes provided. For example, an output of the CMOS corresponding to the external NDMOS is connected to a gate of the external NDMOS, and an output of the CMOS corresponding to the external PDMOS is connected to a gate of the external PDMOS. When a source of a PMOS configuring the CMOS on the NDMOS side and a source of an N MOS configuring the CMOS on the PDMOS side are connected in a shared manner, there is a case where a large current flows through the common impedance (formed of a layout wiring and a bonding wire, for example), biasing is weakly performed between a source and a gate on the PDMOS side, and a leakage current flows, which causes malfunction.

### BRIEF DESCRIPTION OF THE DRAWINGS

FIG. 1 is a diagram illustrating one usage example of a gate driver circuitry;

FIG. 2 is a circuit diagram of a gate driver circuitry according to one embodiment;

FIG. 3 is a circuit diagram of a driver circuitry according to one embodiment;

FIG. 4 is a circuit diagram of a first level shift circuitry according to one embodiment;

FIG. 5 is a circuit diagram of a second level shift circuitry according to one embodiment;

FIG. 6 is a circuit diagram of a third level shift circuitry according to one embodiment;

FIG. 7 is a circuit diagram of a fourth level shift circuitry according to one embodiment;

FIG. 8 is a circuit diagram of a level-down circuitry according to one embodiment;

FIG. 9 is a circuit diagram of a level-up circuitry according to one embodiment;

FIG. 10 is a diagram illustrating one usage example of a gate driver circuitry according to one embodiment;

FIG. 11 is a diagram illustrating one usage example of a gate driver circuitry according to one embodiment;

FIG. 12 is an output example of a gate driver circuitry according to one embodiment; and

FIG. 13 is an output example of a gate driver circuitry according to one embodiment.

### DETAILED DESCRIPTION

According to one embodiment, a gate driver circuitry includes a first driver circuitry including an n-type first transistor, a p-type second transistor, a level-up circuitry, and a level-down circuitry. The second transistor has a drain and a gate which are connected to a drain and a gate, respectively, of the first transistor, and operates at a reference voltage higher than that of the first transistor. The level-up circuitry shifts a voltage applied to the gate of the first transistor to a high-level voltage, and makes the voltage to be fed back to the gate of the second transistor. The level-down circuitry shifts a voltage applied to the gate of the second transistor to a low-level voltage, and makes the voltage to be fed back to the gate of the first transistor. The first driver circuitry outputs a drive voltage of a first power transistor from the drains of the first transistor and the second transistor.

Hereinafter, embodiments will be described while referring to the drawings. Although essential parts of the present embodiment are extracted, this does not mean limitation to exclude the provision of other circuit elements. Further, even if a change is appropriately made except for arrangement of a CMOS, a level shift circuitry, and the like, this does not depart from the range of the present embodiment. Further, although not all of connections of VCC, CND, and the like are illustrated with respect to a buffer circuitry and the like, for example, due to complication of drawings, it is assumed that a connection to a power supply voltage and the like is appropriately made. Further, a numeric value of a voltage and the like used for the explanation is only indicated as one example, and this is not limited to the example and may be appropriately changed according to need.

### First Embodiment

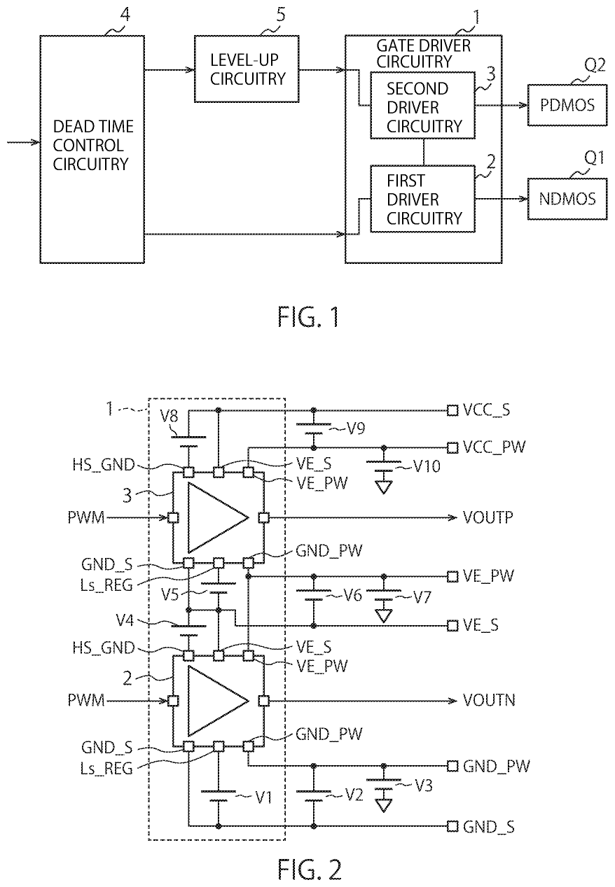

FIG. 1 is a diagram illustrating a usage example of a gate driver circuitry 1 according to the present embodiment. When a switching signal such as PWM is input to a dead time control circuitry 4, dead time control is executed. An output of the dead time control circuitry 4 is input to the gate driver circuitry 1 via a level-up circuitry 5 and in a direct manner. The dead time-controlled PWM signal is directly input to a first driver circuitry 2 and a drive voltage to be applied to a gate of an NDMOS Q1 is generated, and the dead time-controlled PWM signal is input to a second driver circuitry 3 via the level-up circuitry 5 and a drive voltage to be applied to a gate of a PDMOS Q2 is generated, for example. The first driver circuitry 2 and the second driver circuitry 3 may also be connected within the gate driver circuitry 1. Further, in the explanation hereinbelow, the gate driver circuitry 1 is configured by the first driver circuitry 2 and the second driver circuitry 3, but, the present embodiment is not limited to this, and it is also possible to form the gate driver circuitry 1 as a configuration which further includes the dead time control circuitry 4 and the level-up circuitry 5 in a broad sense.

The gate driver circuitry 1 according to the present embodiment includes the first driver circuitry 2 and the second driver circuitry 3 as described above, and the first driver circuitry 2 and the second driver circuitry 3 drive the NDMOS Q1 (a first power transistor) and the PDMOS Q2 (a second power transistor), respectively, which are provided on the outside. Since the driving is performed via the dead time control circuitry 4 and the level-up circuitry 5, short circuit is prevented, a sufficient margin is provided to an on/off switching timing, and besides, the voltages to be applied to the gates of the respective pieces of DMOS are appropriately controlled.

As will be described later, a reference potential of the second driver circuitry 3 is higher than that of the first driver circuitry 2. For example, the first driver circuitry 2 operates when VCC is 8 V and GND is 0 V, and the second driver circuitry 3 operates when VCC is 23 V and GND is 8 V. It is also possible that a level-down circuitry is further provided, depending on a withstand performance of the gate of the PDMOS Q2, between the second driver circuitry 3 and the PDMOS Q2. Hereinafter, a positive-side power supply voltage in each circuitry is simply described as VCC in some cases. In a similar manner, a ground potential is simply described as GND in some cases.

FIG. 2 illustrates one example of a circuit diagram of the gate driver circuitry 1 according to the present embodiment. The gate driver circuitry 1 includes the first driver circuitry 2, the second driver circuitry 3, and voltage sources V1, V2, V3, V4, V5, V6, V7, V8, V9, V10. The voltage sources are not always required to be provided inside the gate driver circuitry 1, and may also be connected, on the outside of the gate driver circuitry 1, so as to add a potential difference between respective terminals. For example, components indicated by a dotted line may be provided inside the gate driver circuitry 1. In this case, each of the voltage sources V2, V3, V6, V7, V9, V10 generates a potential difference between terminals, on the outside. The present embodiment is not limited to this, and a part or all of the voltage sources may also be provided on the outside of the gate driver circuitry 1.

To the first driver circuitry 2, the dead time-controlled input signal PWM is input, and the first driver circuitry 2 applies an output voltage to an output terminal VOUTN which applies a voltage to the gate of the NDMOS Q1. The other terminals include terminals of HS_GND, VE_S, VE_PW, GND_S, Ls_REG, GND_PW, and each of the terminals is appropriately connected between VCC and GND with a potential difference. The internal connection of these terminals will be described later.

To the second driver circuitry 3, the dead time-controlled and level-shifted input signal PWM is input, and the second driver circuitry 3 applies an output voltage to an output terminal VOUTP which applies a voltage to the gate of the PDMOS Q2. The other terminals are similar to those of the first driver circuitry 2.

Each of the first driver circuitry 2 and the second driver circuitry 3 is provided with a complementary MOSFET (which will be described as CMOS, hereinafter), as a circuit element on an output side. A terminal VCC_PW of the gate driver circuitry 1 is connected to a source of a PMOS configuring the CMOS of the second driver circuitry 3. The terminal VE_PW is connected to a source of an NMOS configuring the CMOS of the second driver circuitry 3 and a source of a PMOS configuring the CMOS of the first driver circuitry 2. The terminal GND_PW is connected to a source of an NMOS configuring the CMOS of the first driver circuitry 2. In a manner as above, the voltage between the sources of the CMOS in each of the driver circuitries is applied by VCC_PW and VE_PW, and by VE_PW and GND_PW.

Further, the terminal VCC_S is a VCC sense terminal, and is connected to the power supply voltage VCC, for example. The terminal GND_S is a GND sense terminal, and is connected to the ground voltage GND, for example. By the power supply voltage connected to these sense terminals, a voltage of the gate driver circuitry 1 is supplied.

For example, in FIG. 2, the terminal GND_PW is connected to the source of the external NDMOS Q1, and VOUTN is applied to the gate of the NDMOS Q1. The terminal VCC_PW is connected to the source of the external PDMOS Q2, and VOUTP is applied to the gate of the PDMOS Q2. The drains of the NDMOS Q1 and the PDMOS Q2 are connected to each other to configure the CMOS, and from the drains connected in a shared manner, a switch signal is output. As will be described later, each of V2, V9 is a voltage indicating a difference relative to a sense voltage. These voltages indicate a potential difference relative to the sense voltage when a large current flows through a high-resistance resistor formed of a layout wiring, a bonding wire, and the like to cause short circuit, for example. Ideally, it is desirable that the sources of the NDMOS Q1 and the PDMOS Q2 are connected to GND_S and VCC_S, respectively, but, it is considered that the connection is made in a manner as described above by assuming the short circuit. The present embodiment suppresses malfunction even when this short circuit occurs.

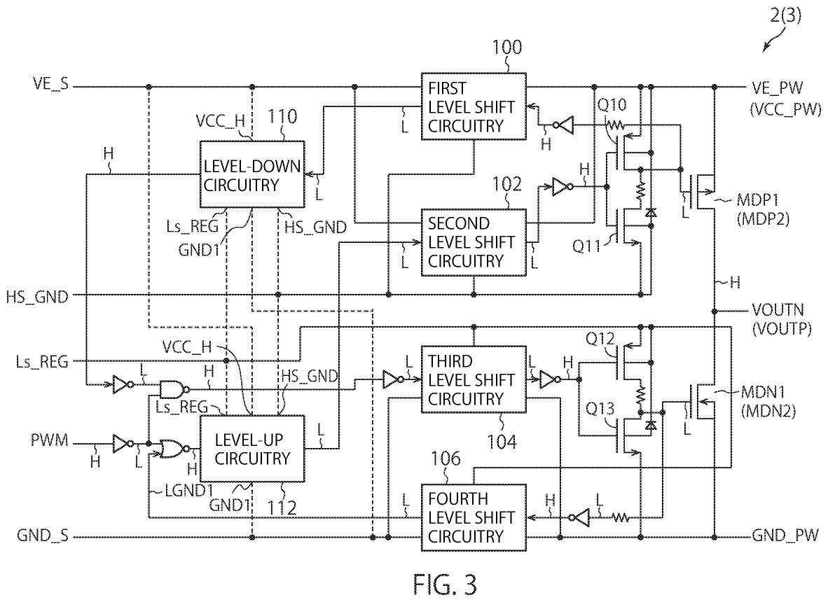

FIG. 3 illustrates one example of a circuit diagram of the first driver circuitry 2 (or the second driver circuitry 3, which is substantially the same as the first driver circuitry 2). In this example, a case where a High signal is input as PWM is indicated. H and L in the drawing indicate High and Low, respectively. When a Low signal is input, a state where H and L in the drawing are switched is created.

The first driver circuitry 2 includes a first level shift circuitry 100, a second level shift circuitry 102, a third level shift circuitry 104, a fourth level shift circuitry 106, a level-down circuitry 110, and a level-up circuitry 112. The first driver circuitry 2 further includes an NMOS MDN1 (a first transistor) and a PMOS MDP1 (a second transistor) as a CMOS which applies a voltage to the gate of the first power transistor NDMOS Q1, and from drains of these transistors, a drive voltage VOUTN to be applied to the gate of the NDMOS is output.

In the case of the second driver circuitry 3 being a circuitry which drives the PDMOS Q2, the CMOS at the last stage is configured as an MDN2 (a third transistor) and an MDP2 (a fourth transistor). The second driver circuitry 3 outputs, from drains of these transistors, a drive voltage VOUTP to be applied to the gate of the second power transistor PDMOS Q2.

An operation of the gate driver circuitry 1 will be described by using FIG. 2 and FIG. 3. To the gate driver circuitry 1, for example, VCC=23 V and GND=0 V are applied as the power supply voltage. Specifically, the terminal VCC_S is connected to 23 V, and the terminal GND_S is connected to 0 V.

The voltage source V1 is a voltage source for providing a potential difference between the terminal GND_S and the terminal Ls_REG of the first driver circuitry 2. The voltage source V4 is a voltage source for providing a potential difference between the terminal VE_S and the terminal Hs_GND of the first driver circuitry 2. The voltage source V5 is a voltage source for providing a potential difference between the terminal VE_S and the terminal Ls_REG of the second driver circuitry 3. The voltage source V8 is a voltage source for providing a potential difference between the terminal VCC_S and the terminal HS_GND of the second driver circuitry 3. Each of these voltage sources V1, V4, V5, V8 defines a voltage between input/output terminals of the transistor (between the drain and the source, or between the source of the PMOS and the source of the NMOS in the CMOS) in the first driver circuitry 2 or the second driver circuitry 3, and applies a voltage of 5 V, for example.

Each of the voltage sources V3, V7, V10 is a voltage source which raises an electric potential of each terminal from the ground voltage, and, for example, the voltage source V3 applies a voltage of 0 V, the voltage source V7 applies a voltage of 8 V, and the voltage source V10 applies a voltage of 23 V.

The voltage source V2 is a voltage source which virtually represents a potential difference between the terminals GND_S and GND_PW of the first driver circuitry 2. The voltage source V6 is a voltage source which virtually represents a potential difference between the terminals VE_PW and VE_S of the first driver circuitry 2 and a potential difference between the terminals GND_S and GND_PW of the second driver circuitry 3. The voltage source V9 is a voltage source which virtually represents a potential difference between the terminals VCC_PW and VCC_S of the second driver circuitry 3.

An output of these virtual voltage sources is ideally 0 V, for example. However, when packaging or the like is performed, short circuit sometimes occurs via a path of a high-resistance resistor. Such short circuit via the high-resistance resistor is virtually provided. In the present embodiment, by using the first driver circuitry 2 and the second driver circuitry 3, even when values of these V2, V6, V9 have a certain degree of magnitude, it becomes possible to stably drive the NDMOS Q1 and the PDMOS Q2, or the complementary DMOS (CDMOS) formed by combining the NDMOS Q1 and the PDMOS Q2.

The first driver circuitry 2 uses the CMOS including the PMOS MDP1 and the NMOS MDN1 to output VOUTN. The CMOS switches the voltage to be applied to the gate of the NDMOS Q1 illustrated in FIG. 1 based on the voltage applied to the gates of the respective transistors.

The first level shift circuitry 100 is a circuitry which switches a High/Low state of input/output, and level-shifts an amplitude between VE_PW and HS_GND to an amplitude between VE_S and HS_GND. The second level shift circuitry 102 is a circuitry which level-shifts an amplitude between VE_S and HS_GND to an amplitude between VE_PW and HS_GND while keeping a High/Low state of input/output.

The third level shift circuitry 104 is a circuitry which level-shifts an amplitude between Ls_REG and GND_S to an amplitude between Ls_REG and GND_PW while keeping a High/Low state of input/output. The fourth level shift circuitry 106 is a circuitry which switches a High/Low state of input/output, and level-shifts an amplitude between Ls_REG and GND_PW to an amplitude between Ls_REG and GND_S.

FIG. 3 illustrates a stable state when a High signal is input as the PWM signal. A path indicated by a dotted line indicates connection from VCC and GND to the level-down circuitry 110 and the level-up circuitry 112, and is indicated by the dotted line for the purpose of easiness to view. The level-down circuitry 110 is a circuitry which inverts input/output signals and performs level-down of an amplitude between VCC_H (VE_S) and HS_GND to an amplitude between Ls_REG and GND1 (GND_S). The level-up circuitry 112 is a circuitry which inverts input/output signals and performs level-up of an amplitude between Ls_REG and GND1 (GND_S) to an amplitude between VCC_H (VE_S) and HS_GND. In other words, the level-down circuitry 110 is a circuitry which converts a VCC-reference signal into a GND-reference signal, and the level-up circuitry 112 is a circuitry which converts a GND-reference signal into a VCC-reference signal.

PWM being the input signal is a High signal, and it is turned into a Low signal by a NOT circuitry. This Low signal is input to a NOR circuitry together with an output of the fourth level shift circuitry 106. When an output of the fourth level shift circuitry 106 is in a Low state, an output of the NOR circuitry becomes a High state. The Low signal having an amplitude between Ls_REG and GND_S is input to the level-up circuitry 112. The signal is converted into a High signal having an amplitude between VE_S and HS_GND in the level-up circuitry 112.

This signal is converted into a Low signal between VE_PW and HS_GND in the second level shift circuitry 102. The Low signal is converted into a High signal in a NOT circuitry, and applied to gates of a PMOS Q10 and an NMOS Q11 configuring a CMOS. The CMOS to which the High signal is applied, outputs a Low signal from its drain. Subsequently, the Low signal between VE_PW and HS_GND is applied to the gate of the PMOS MDP1.

The voltage applied to the gate is fed back to a signal to be applied to the gate of the NMOS MDN1 configuring the CMOS. First, the voltage is converted into a High signal by a NOT circuitry and input to the first level shift circuitry 100. The first level shift circuitry 100 level-shifts the input signal to a Low signal between VE_S and HS_GND. This Low signal is input to the level-down circuitry 110, and converted into a High signal between Ls_REG and GND_S. An output of the level-down circuitry 110 is input to a NAND circuitry via a NOT circuitry together with a negation of the PWM signal, and a High signal is output. An output of the NAND circuitry is converted into a Low signal via a NOT circuitry, and then input to the third level shift circuitry 104.

The third level shift circuitry 104 converts the input Low signal between Ls_REG and GND_S into a Low signal between Ls_REG and GND_PW. The signal converted in the third level shift circuitry 104 is applied to gates of a PMOS Q12 and an NMOS Q13 configuring a CMOS via a NOT circuitry. The CMOS to which a High signal is applied, outputs a Low signal from its drain. Further, the Low signal between Ls_REG and GND_PW is applied to the gate of the NMOS MDN1.

The voltage applied to the gate is fed back to the level-up circuitry 112 via a NOT circuitry and the fourth level shift circuitry 106. In a manner as described above, in the first level shift circuitry 100 and the fourth level shift circuitry 106, the level is converted into the signal between Ls_REG and GND_S being the level of the input PWM signal, to be fed back.

Since the Low signal s applied to the gate of the PMOS MDP1 and the gate of the NMOS MDN1 configuring the CMOS as described above, a High signal is output to the gate of the NDMOS Q1 illustrated in FIG. 1.

A similar operation is performed also in the second driver circuitry 3. However, in the second driver circuitry 3, VCC_PW is connected to the VE_PW terminal, VCC_S is connected to the V_ES terminal, VCC_S whose voltage is dropped by the voltage source V8 is connected to HS_GND, VE_S to which a voltage is applied by the voltage source V5 is connected to the Ls_REG terminal, VE_PW is connected to the GND_PW terminal, and VE_S is connected to the GND_S terminal. In a state where the connection is made as described above, a High or Low signal is applied to the gates of the PMOS MDP2 and the NMOS MDN2 configuring the CMOS, and a Low or High signal is output to the gate of the PDMOS Q2 illustrated in FIG. 1.

As can be understood from FIG. 2 and FIG. 3, the GND_PW terminal of the second driver circuitry 3 and the VE_PW terminal of the first driver circuitry 2, namely, the source of the NMOS MDN2 of the second driver circuitry 3 and the source of the PMOS MDP1 of the first driver circuitry 2 are connected. For example, when outputs of the first driver circuitry 2 and the second driver circuitry 3 are set to High states (when a power switch is tried to be turned off), it is assumed that a large current flows through a combined resistor Rpara of a layout wiring and a bonding wire between the VE_PW terminal of the first driver circuitry 2 and the GND_PW terminal of the second driver circuitry 3.

Also in such a case, the feedback of the gate voltage of the NMOS MDN2 converted by the fourth level shift circuitry 106 of the second driver circuitry 3 is performed based on the voltage of the GND_PW terminal of the second driver circuitry 3, namely, the source of the NMOS MDN2. The GND level is converted by the fourth level shift circuitry 106, and the fed-back voltage is input to the third level shift circuitry 104 via the second level shift circuitry 102 and the first level shift circuitry 100. In the third level shift circuitry 104, the reference of GND is converted from GND_S into GND_PW.

This makes it possible to appropriately control the reference level of the voltage to be applied to the gate of the NMOS MDN2, and keep the voltage between the gate and the source to be smaller than a threshold voltage |Vth| of the NMOS MDN2, resulting in that the generation of leakage current in the NMOS MDN2 can be suppressed.

In like manner, it is assumed that a large current flows through the combined resistor Rpara when the outputs of the first driver circuitry 2 and the second driver circuitry 3 are set to Low states (when the power switch is tried to be turned on).

Also in such a case, the feedback of the gate voltage of the PMOS MDP1 converted by the first level shift circuitry 100 of the first driver circuitry 2 is performed based on the voltage of the VE_PW terminal of the first driver circuitry 2, namely, the source of the PMOS MDP1. The VCC level is converted by the first level shift circuitry 100, and the fed-back voltage is input to the second level shift circuitry 102 via the third level shift circuitry 104 and the fourth level shift circuitry 106. In the second level shift circuitry 102, the reference of VCC is converted from VE_S into VE_PW.

This makes it possible to appropriately control the reference level of the voltage to be applied to the gate of the PMOS MDP1, and keep the voltage between the gate and the source to be smaller than a threshold voltage |Vth| of the PMOS MDP1, resulting in that the generation of leakage current in the PMOS MDP1 can be suppressed.

As described above, according to the present embodiment, even in a case where, when driving the pieces of power MOSFET configuring the CMOS, a potential difference is generated between the sources of the pieces of CMOS in a previous stage of generating the voltages to be applied to the gates of the respective pieces of power MOSFET, it becomes possible to suppress the leakage current between the pieces of CMOS in the previous stage.

Hereinafter, the respective level shift circuitries including the level-down circuitry 110 and the level-up circuitry 112 will be briefly described by citing one example. Note that in the respective level shift circuitries hereinbelow, when High and Low of an input signal are opposite, an operation in which High and Low are inverted is made.

Each of the first level shift circuitry 100, the second level shift circuitry 102, the third level shift circuitry 104, and the fourth level shift circuitry 106 is a small-signal CMOS logic circuitry. A logical amplitude of these circuitries is set to about 5 V, but, it may also be changed according to the design of the gate driver circuitry 1.

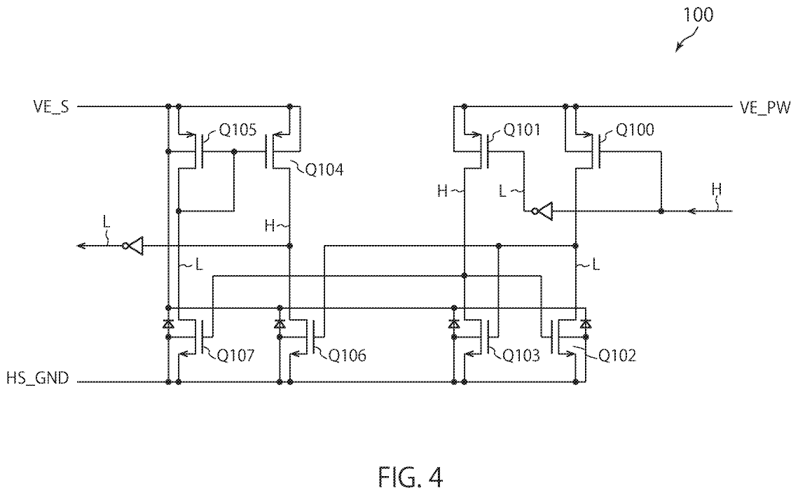

FIG. 4 is a circuit diagram illustrating one example of the first level shift circuitry 100. The first level shift circuitry 100 includes, for example, transistors Q100, Q101, Q102, Q103, Q104, Q105, Q106, Q107, and two NOT circuitries. For example, each of the transistors Q100, Q101, Q104, Q105 is a P-type MOSFET, and each of the transistors Q102, Q103, Q106, Q107 is an N-type MOSFET.

It is assumed that a High signal in which VE_PW is set as a VCC reference is input to the first level shift circuitry 100. In this case, a High signal is applied to a gate of the transistor Q100, and a drain side of the transistor becomes a Low state. A Low signal is applied to a gate of the transistor Q101 and a gate of the transistor Q103, and a drain side of each of the transistors becomes a High state. In a similar manner, a High signal is applied to a gate of the transistor Q102, and a drain side of the transistor shared with the transistor Q100 becomes a Low state.

Each of the signals on the drain sides is applied to the gate of the NMOS, A High signal is applied to a gate of the transistor Q107, so that a current flowed from a drain of the transistor Q105 to a source of the transistor Q107 via a drain of the transistor Q107 flows to HS_GND, resulting in that a Low state is created between the drains of the transistors Q105 and Q107. For this reason, a Low signal is applied to a gate of the transistor Q104, resulting in that a High state is created between a drain of the transistor Q104 and a drain of the transistor Q106 in which a Low signal is also applied to a gate thereof. Here, the reference of VCC is the VCC reference of the transistor Q104, so that a signal converted into a level of VE_S is output via a NOT circuitry. In a case of the drawing, a Low signal is output from the first level shift circuitry 100 via a NOT circuitry.

In a manner as described above, the first level shift circuitry 100 converts the VCC reference from VE_PW into VE_S, and performs an output by converting a state of input/output into an opposite state.

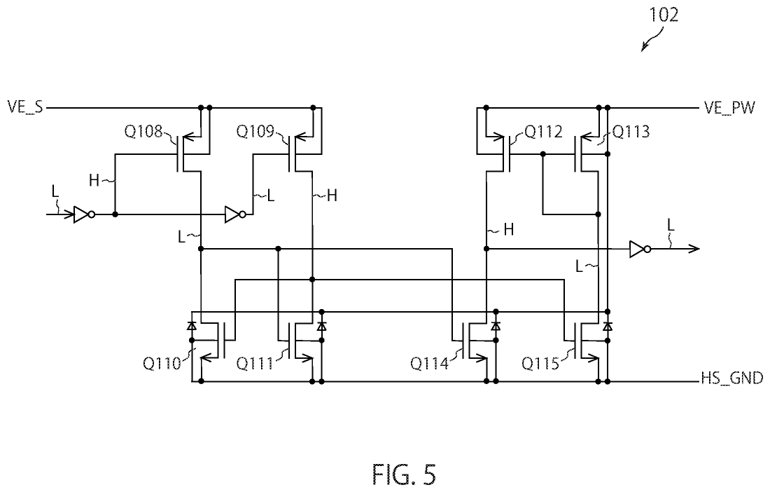

FIG. 5 is a circuit diagram illustrating one example of the second level shift circuitry 102. The second level shift circuitry 102 includes transistors Q108, Q109, Q112, Q113 each being a PMOS, for example, and transistors Q110, Q111, Q114, Q115 each being an NMOS, for example.

It is assumed that a Low signal in which VE_S is set as the VCC reference is input to the second level shift circuitry 102. In this case, a High signal is applied to a gate of the transistor Q108 via a NOT circuitry, and a Low signal is applied to a gate of the transistor Q109 via the above-described NOT circuitry and another NOT circuitry. Further, a High signal is applied to a gate of the transistor Q110, and a Low signal is applied to a gate of the transistor Q111.

To gates of the transistors Q114, Q115 connected to drains of these transistors, a Low signal and a High signal are applied, respectively, and a Low signal is applied to each of gates of the transistors Q112, Q113. For this reason, each of drains of the transistors Q112, Q114 is turned into a High state in which the VCC reference is converted into VE_PW, As a result of this, a Low signal is output from the second level shift circuitry 102 via a NOT circuitry.

In a manner as described above, the second level shift circuitry 102 converts the VCC reference from VE_S into VE_PW, and performs an output while keeping a state of input/output.

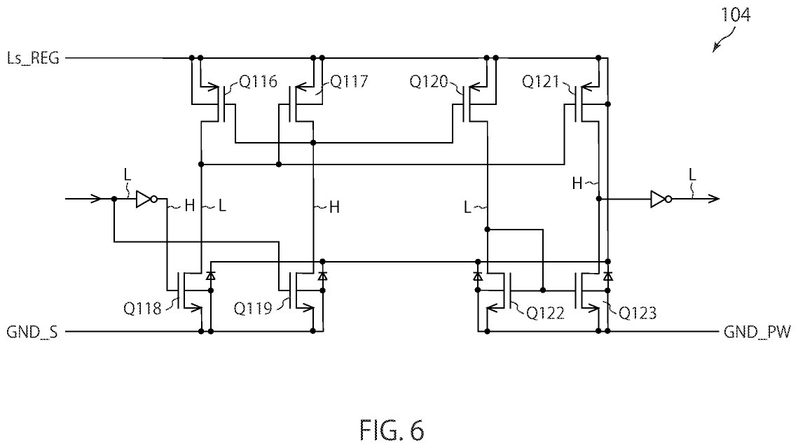

FIG. 6 is a circuit diagram illustrating one example of the third level shift circuitry 104. The third level shift circuitry 104 includes transistors Q116, Q117, Q120, Q121 each being a PMOS, for example, and transistors Q118, Q119, Q122, Q123 each being an NMOS, for example.

It is assumed that a Low signal in which GND_S is set as the GND reference is input to the third level shift circuitry 104. In this case, a High signal is applied to a gate of the transistor Q118 via a NOT circuitry, and a Low signal is applied to a gate of the transistor Q119. Further, a High signal is applied to a gate of the transistor Q116, and a Low signal is applied to a gate of the transistor Q117.

To gates of the transistors Q120, Q121 connected to drains of these transistors, a High signal and a Low signal are applied, respectively, and a Low signal is applied to each of gates of the transistors Q122, Q123. For this reason, each of drains of the transistors Q121, Q123 is turned into a High state in which the GND reference is converted into GND_PW. As a result of this, a Low signal is output from the third level shift circuitry 104 via a NOT circuitry.

In a manner as described above, the third level shift circuitry 104 converts the GND reference from GND_S into GND_PW, and performs an output while keeping a state of input/output.

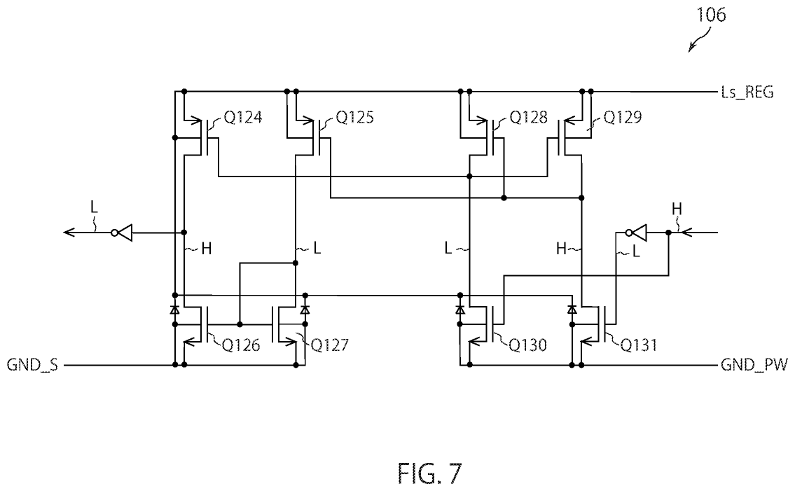

FIG. 7 is a circuit diagram illustrating one example of the fourth level shift circuitry 106. The fourth level shift circuitry 106 includes transistors Q124, Q125, Q128, Q129 each being a PMOS, for example, and transistors Q126, Q127, Q130, Q131 each being an NMOS, for example.

It is assumed that a High signal in which GND_PW is set as the GND reference is input to the fourth level shift circuitry 106. In this case, a Low signal is applied to a gate of the transistor Q131 via a NOT circuitry, and a High signal is applied to a gate of the transistor Q130. Further, a High signal is applied to a gate of the transistor Q128, and a Low signal is applied to a gate of the transistor Q129.

To gates of the transistors Q124, Q125 connected to drains of these transistors, a Low signal and a High signal are applied, respectively, and a Low signal is applied to each of gates of the transistors Q126, Q127. For this reason, each of drains of the transistors Q124, Q126 is turned into a High state in which the GND reference is converted into GND_S. As a result of this, a Low signal is output from the fourth level shift circuitry 106 via a NOT circuitry.

In a manner as described above, the fourth level shift circuitry 106 converts the GND reference from GND_PW into GND_S, and performs an output by inverting a state of input/output.

Next, explanation will be made on the level-down circuitry 110 and the level-up circuitry 112 converting a voltage level of a signal fed back from the gates of the transistors MDP1, MDN1, MDP2, MDN2, namely, the first level shift circuitry 100 and the fourth level shift circuitry 106. Each of the level-down circuitry 110 and the level-up circuitry 112 is a high-withstand-voltage level shift circuitry.

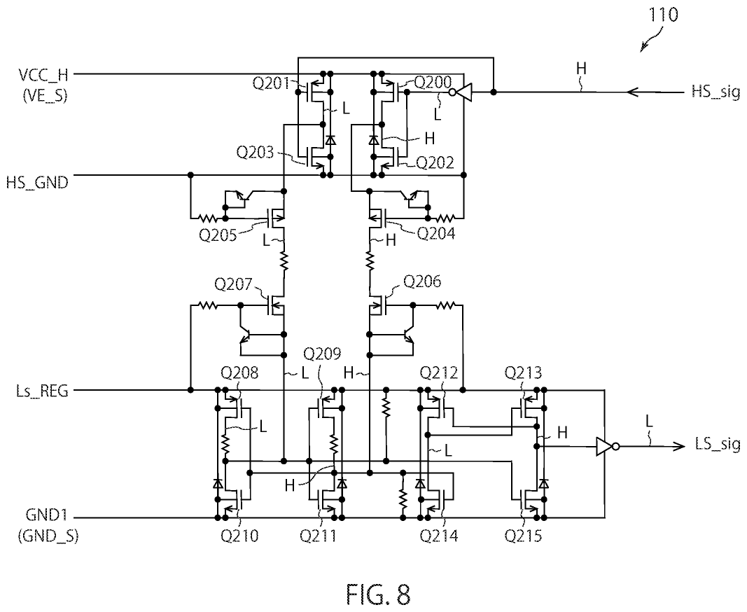

FIG. 8 is a circuit diagram illustrating one example of the level-down circuitry 110. According to FIG. 3, to the level-down circuitry 110, a signal HS_sig in which VE_S and HS_GND are set as a reference is input. As indicated in parentheses in FIG. 8, a voltage of V_ES is applied to the VCC_H terminal, and a voltage of GND_S is applied to the GND1 terminal. Further, a case where a High signal is input to the level-down circuitry 110 will be described.

The level-down circuitry 110 includes transistors Q200, Q201, Q204, Q205, Q208, Q209, Q212, Q213 each being a PMOS, for example, and transistors Q202, Q203, Q206, Q207, Q210, Q211, Q214, Q215 each being an NMOS, for example.

A Low signal is applied to each of gates of the transistors Q200, Q202 via a NOT circuitry, which makes drains of the transistors turn into High states, and a High signal is applied to each of gates of the transistors Q201, Q203, which makes drains of the transistors turn into Low states.

A High signal and HS_GND are applied to a source and a gate, respectively, of the transistor Q204, so that to a drain of the transistor, a High signal in which a Low level is suppressed by HS_GND is output. A Low signal and HS_GND are applied to a source and a gate, respectively, of the transistor Q205, so that to a drain of the transistor, a Low signal in which a Low level is suppressed by HS_GND is output. A High signal and Ls_REG are applied to a drain and a gate, respectively, of the transistor Q206, so that to a source of the transistor, a High signal in which a High level is suppressed by Ls_REG is output. A Low signal and Ls_REG are applied to a drain and a gate, respectively, of the transistor Q207, so that to a source of the transistor, a Low signal in which a High level is suppressed by Ls_REG is output.

A High signal is input to each of gates of the transistors Q208, Q210, and from each of drains of the transistors, a Low signal in which the GND reference is converted into GND_S is output. A Low signal is applied to each of gates of the transistors Q209, Q211, and from each of drains of the transistors, a High signal in which the GND reference is converted into GND_S is output.

A High signal is applied to a gate of the transistor Q214, so that a source of the transistor has a Low level, and a gate of the transistor Q213 is turned into a Low state. Further, since the gate of the transistor Q213 is in a Low state, from a drain of the transistor Q215 in which a Low signal is applied to a gate thereof, a High signal is output. Further, this High signal is applied to a gate of the transistor Q212, which makes drains of the transistors Q212, Q214 turn into Low states.

As a result of this, the signal LS_sig to be output becomes a Low signal in which the reference thereof is converted into Ls_REG and GND_S. In a manner as described above, the level-down circuitry 110 inverts a High/Low state of input, converts a signal in which VE_S and HS_GND are set as a reference into a signal in which Ls_REG and GND_S are set as a reference, and outputs the converted signal.

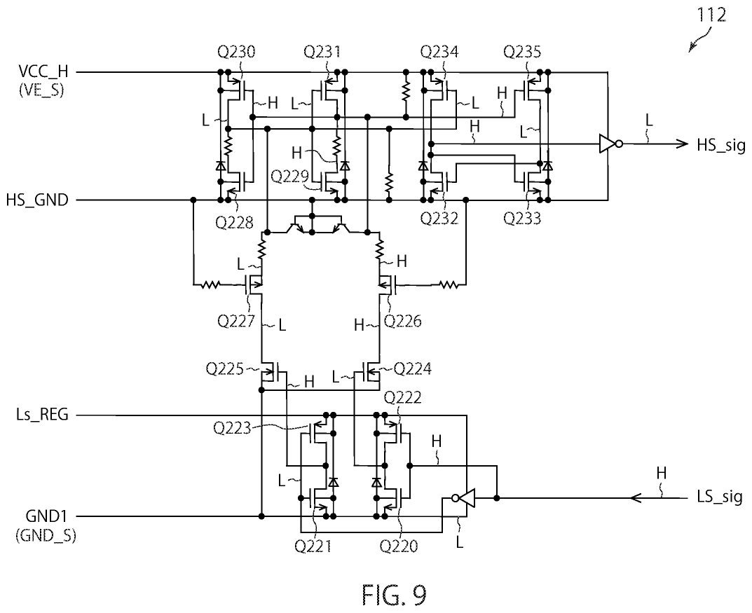

FIG. 9 is a circuit diagram illustrating one example of the level-up circuitry 112 in FIG. 3. According to FIG. 3, to the level-up circuitry 112, a signal LS_sig in which Ls_REG and GND_S are set as a reference is input. As indicated in parentheses in FIG. 9, a voltage of VE_S is applied to the VCC_H terminal, and a voltage of GND_S is applied to the GND1 terminal. Further, a case where a High signal is input to the level-up circuitry 112 will be described.

The level-up circuitry 112 includes transistors Q220, Q221, Q224, Q225, Q228, Q229, Q232, Q233 each being an NMOS, for example, and transistors Q222, Q223, Q226, Q227, Q230, Q231, Q234, Q235 each being a PMOS, for example.

A High signal is applied to each of gates of the transistors Q220, Q222, which makes drains of the transistors turn into Low states, and a Low signal is applied to each of gates of the transistors Q221, Q223 via a NOT circuitry, which makes drains of the transistors turn into High states.

A High signal is applied to a gate of the transistor Q225, and a Low signal is applied to a gate of the transistor Q227, so that these two transistors are turned on. Besides, a source of the transistor Q225 is connected to GND_S, so that a drain of the transistor Q225, and a drain and a source of the transistor Q227 are turned into Low states.

Gates of the transistors Q229, Q231 are turned into Low states, so that drains of these transistors are turned into High states. As a result of this, a source of the transistor Q226 is turned into a High state. HS_GND (Low signal) is applied to a gate of the transistor Q226, and a Low signal is applied to a gate of the transistor Q224, so that drains of the transistors Q226, Q224 are turned into High states.

A High signal in which VE_S and HS_GND are set as a reference is applied to each of gates of the transistors Q228, Q230, resulting in that drains of the transistors are turned into Low states. In a similar manner, a voltage to be a reference is converted into VE_S and HS_GND in a transistor of an upper stage.

Accordingly, a Low signal is applied to a gate of the transistor Q234, a High signal is applied to a gate of the transistor Q235, a Low voltage is applied to a gate of the transistor Q232, and a High voltage is applied to a gate of the transistor Q233. The reference of these signals becomes VE_S and HS_GND.

As a result of this, a Low signal in which VCC_H and HS_GND are set as a reference, is output from the level-up circuitry 112. In a manner as described above, the level-up circuitry 112 inverts a High/Low state of input, converts a signal in which Ls_REG and GND_S are set as a reference into a signal in which VE_S and HS_GND are set as a reference, and outputs the converted signal.

The level-up circuitry 5 illustrated in FIG. 1 and so on may be a circuitry which is similar to the level-up circuitry 112 and which appropriately adjusts a High/Low state of output, and it may also be a circuitry having another configuration.

Note that each of the level shift circuitries is not limited to one illustrated in FIG. 4 to FIG. 9, and may also be one which appropriately converts a state High/Low of an input/output signal and converts a level reference of VCC or GND.

Further, although both the first driver circuitry 2 and the second driver circuitry 3 are designed to be provided in the present embodiment, it is also possible to configure that only the first driver circuitry 2 is provided when, for example, the power transistor is only the NDMOS. By providing the first driver circuitry 2 as described above, it is also possible to similarly suppress a leakage current in a state where a switch is turned off regarding a power transistor being an output destination.

### Second Embodiment

It is also possible that an output of the above-described embodiment is monitored, and is further fed back. In the present embodiment, output signals of the first driver circuitry 2 and the second driver circuitry 3 are fed back to a dead time control circuitry.

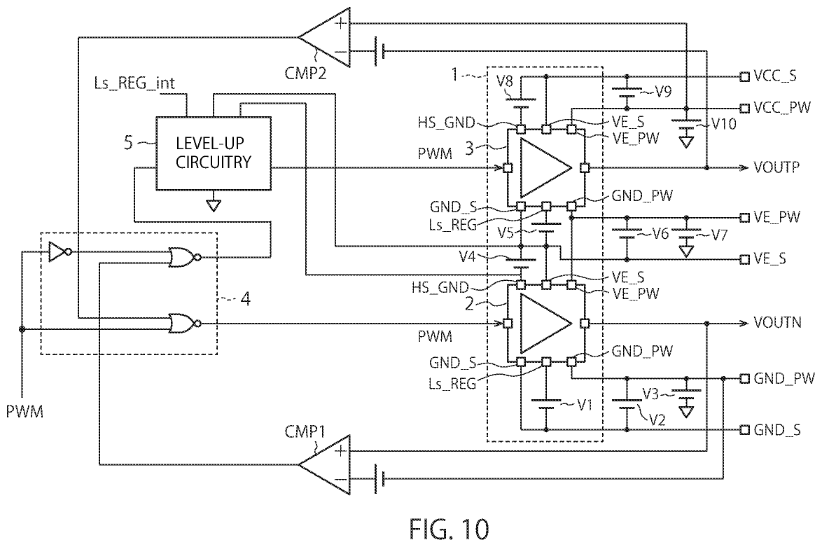

FIG. 10 illustrates an example of mounting a gate driver circuitry according to the present embodiment. An output signal of the gate driver circuitry 1 is fed back to the dead time control circuitry 4 via comparison circuitries CMP1, CMP2.

The comparator CMP1 monitors an output signal on the external NDMOS Q1 side being an output of the first driver circuitry 2, The comparator CMP1 compares VOUTN being the output signal and a ground potential (an electric potential of the terminal GND_PW), in which, for example, when the output signal VOUTN is larger than the ground potential GND_PW by about a threshold voltage Vth (for example, about 1.5 V) or more of the external NDMOS Q1, the comparator CMP1 outputs a High signal, and in a case other than the above, the comparator CMP1 outputs a Low signal. By performing the monitoring as above, the short circuit of the external NDMOS Q1 is avoided based on a control as a result the monitoring.

When a negation of a logical sum of the output of the comparator CMP1 and a negation of the input of the input signal PWM is set as an input of the second driver circuitry 3, an output of the second driver circuitry 3 is made to transit from a High state to a Low state after an output of the first driver circuitry 2 is transited from a High state to a Low state. Specifically, when the input signal transits from a Low state to a High state, the output of the first driver circuitry 2 transits to a Low state precedently before the output of the second driver circuitry 3 is transited to a Low state.

The comparator CMP2 monitors an output signal on the external PDMOS Q2 side being an output of the second driver circuitry 3. The comparator CMP2 compares VOUTP being the output signal and a power supply potential (for example, an electric potential of VCC_PW), in which, for example, when the output signal VOUTP is lower than the power supply voltage VCC_PW by about an absolute value of a threshold voltage Vth (for example, about 1.5 V) or more of the external PDMOS Q2, the comparator CMP2 outputs a High signal, and in a case other than the above, the comparator CMP2 outputs a Low signal. By performing the monitoring as above, the short circuit of the external PDMOS Q2 is avoided based on a control as a result the monitoring.

When a negation of a logical sum of the output of the comparator CMP2 and the input of the input signal PWM is set as an input of the first driver circuitry 2, an output of the first driver circuitry 2 is made to transit from a Low state to a High state after an output of the second driver circuitry 3 is transited from a Low state to a High state. Specifically, when the input signal transits from a High state to a Low state, the output of the second driver circuitry 3 transits to a High state precedently before the output of the first driver circuitry 2 is transited to a High state.

Similarly to FIG. 2, the terminal GND_PW is connected to the source of the external NDMOS Q1, and VOUTN is applied to the gate of the NDMOS Q1, The terminal VCC_PW is connected to the source of the external PDMOS Q2, and VOUTP is applied to the gate of the PDMOS Q2. The drains of the NDMOS Q1 and the PDMOS Q2 are connected to each other to configure the CMOS, and from the drains connected in a shared manner, a switch signal is output.

As described above, according to the present embodiment as well, even in a case where, when driving the pieces of power MOSFET configuring the CMOS, a potential difference is generated between the sources of the pieces of CMOS in a previous stage of generating the voltages to be applied to the gates of the respective pieces of power MOSFET, it becomes possible to suppress the leakage current between the pieces of CMOS in the previous stage. Besides, by making the outputs of the respective driver circuitries to be fed back, it becomes possible to turn off one of the pieces of DMOS and then turn on the other DMOS, and thus both of the two pieces of DMOS are prevented from being turned on simultaneously, which enables to improve stability and safety of the power MOS switch.

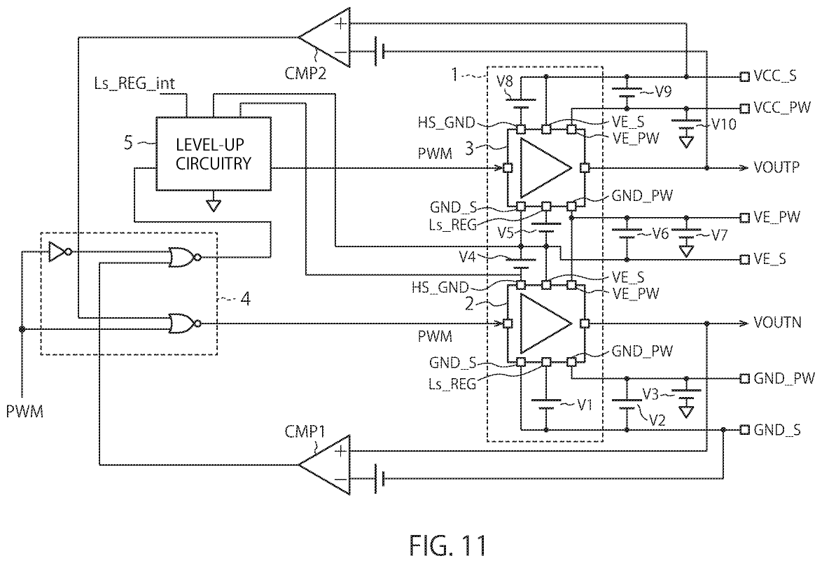

The present embodiment may also be modified in a manner as in FIG. 11. Specifically, an inverting terminal of the comparator CMP1 is connected to the terminal GND_S, and a non-inverting terminal of the comparator CMP2 is connected to the terminal VCC_S. By the connection as above, it is also possible to monitor an electric potential of each terminal of the external NDMOS Q1, PDMOS Q2, similarly to the above. As a result of this, by making the comparison result to be fed back to the gate driver circuitry 1, it becomes possible to avoid the short circuit of the external NDMOS Q1, PDMOS Q2.

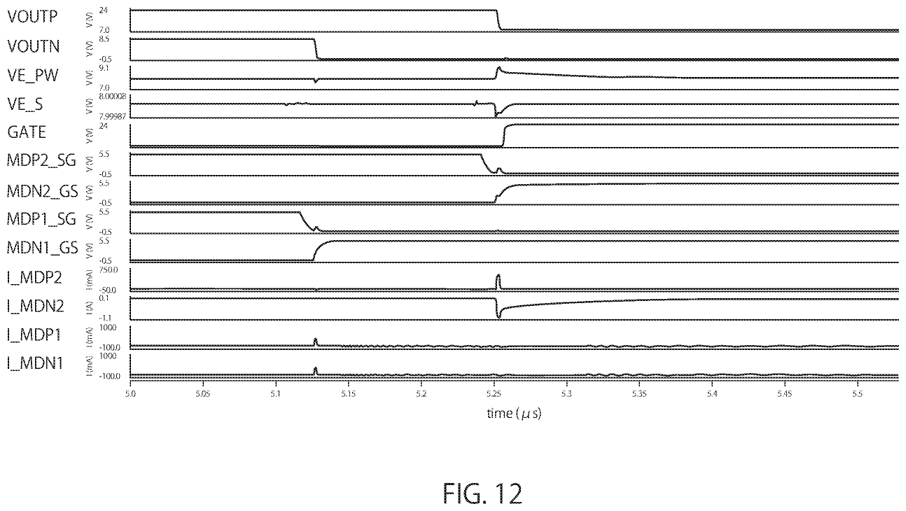

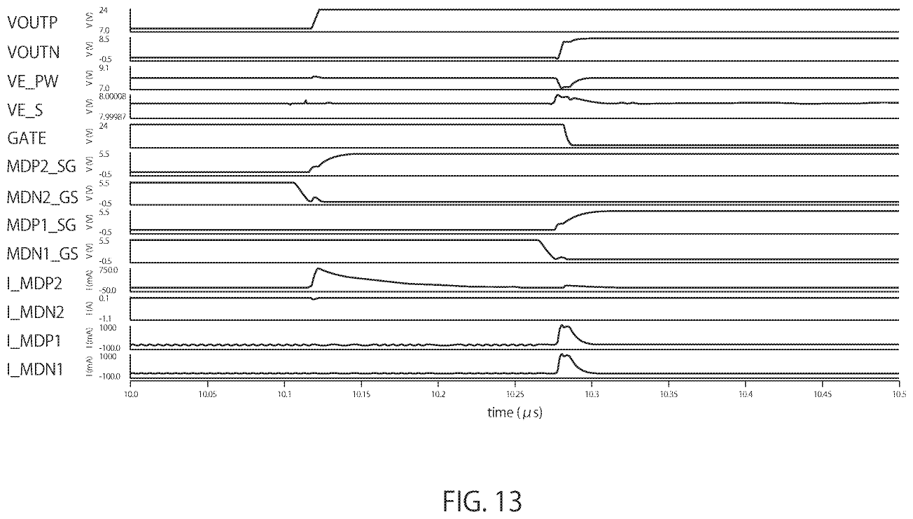

Each of FIG. 12 and FIG. 13 illustrates respective signals when, in the gate driver circuitry 1 according to the first embodiment, short circuit occurs between VCC_S and VCC_PW, between VE_PW and VE_S, and between GND_PW and GND_S, via a resistor of 1Ω. For example, 5 us is set as a reference, and the input PWM is set to a Low state at 5 us, and the input PWM is set to a High state at 10 us. A dead time is set to be 0.125 us at each timing.

In these drawings, VOUTP, VOUTN, VE_PW, VE_S, an output GATE from the drains of the PDMOS Q2 and the NDMOS Q1, a source-gate voltage MDP2_SG of the MDP2, a gate-source voltage MDN2_GS of the MDN2, a source-gate voltage MDP1_SG of the MDP1, a gate-source voltage MDN1_GS of the MDN1, a drain current I_MDP2 of the MDP2, a drain current I_MDN2 of the MDN2, a drain current I_MDP1 of the MDP1, and a drain current I_MDN1 of the MDN1, are illustrated in order from the top.

FIG. 12 is a diagram illustrating a state where the input PWM is set to a Low state at 5 us. At a timing after 0.125 us, VOUTN becomes a Low state. After 0.25 us, VOUTP becomes a Low state, and Gate becomes a High state, namely, a switch is turned on, and on the other hand, the drain current I_MDP1 does not change almost at all. As described above, the drain current I_MDP1 does not flow at a timing at which the PDMOS Q2 is turned on, so that malfunction can be suppressed.

FIG. 13 is a diagram illustrating a state where the input PWM is set to a High state at 10 us. At a timing after 0.125 us, VOUTP becomes a High state. After 0.25 us, VOUTN becomes a High state, and Gate becomes a Low state, namely, a switch is turned off, and on the other hand, the drain current I_MDN2 does not change almost at all. As described above, the drain current I_MDN2 does not flow at a timing at which the NDMOS Q1 is turned on, so that malfunction can be suppressed.

As described above, when considering a case where biasing is performed by setting VCC to 23 V, the middle of output terminals of VOUTP and VOUTN to 8 V, and GND to 0 V, it is possible to obtain the results as in FIG. 12, FIG. 13.

According to the respective embodiments described above, by using the first level shift circuitry 100 and the third level shift circuitry 104, it becomes possible to prevent malfunction due to voltage drop of IR_Drop in a parasitic resistor Rs (a resistor formed of, for example, a wiring within IC and a bonding wire) between a PW wiring and a sense wiring.

Besides, it becomes possible to avoid that the MDP2 and the MDN1 are erroneously turned on by a back electromotive voltage V=−Ls×dI/dt at an off-timing in a parasitic inductance (for example, a wiring within IC and a bonding wire) between VCC_PW and VCC_S, and a parasitic inductance between GND_PW and GND_S.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

For example, the output destination of the first driver circuitry is set to the n-type DMOS, but, the present invention is not limited to this. As another example, it is also possible that the first driver circuitry is connected to an insulated gate bipolar transistor (IGBT), and control of the IGBT is performed. Specifically, when the first driver circuitry is used, the output destination of the first driver circuitry may be set to the n-channel IGBT. To set an appropriate power transistor to the output destination of the driver circuitry as described above, can also be set to fall within a range of the respective embodiments described above. Besides, the other pieces of MOSFET can also be replaced with bipolar transistors and the like, for example, as long as performances, easiness of process, and so on are appropriate.

1. A gate driver circuitry, comprising
a first driver circuitry, wherein:
the first driver circuitry comprises:
an n-type first transistor;
a p-type second transistor having a drain which is connected to a drain of the first transistor, and operating at a reference voltage higher than that of the first transistor;
a level-up circuitry converting a GND-reference signal of the first driver circuitry into a VCC-reference signal of the first driver circuitry; and
a level-down circuitry converting the VCC reference signal of the first driver circuitry into the GND-reference signal of the first driver circuitry; and
a gate of a first power transistor is connected with the drains of the first transistor and the second transistor.

2. The gate driver circuitry according to claim 1, wherein
a positive-side power supply potential applied to the gate of the first transistor is an electric potential equal to or lower than a ground potential applied to the gate of the second transistor.

3. The gate driver circuitry according to claim 1, further comprising
a second driver circuitry having a configuration same as that of the first driver circuitry, wherein:
the second driver circuitry comprises:
an n-type third transistor;
a p-type fourth transistor having a drain which is connected to a drain of the third transistor, and operating at a reference voltage higher than that of the third transistor;
a level-up circuitry converting a GND-reference signal of the second driver circuitry into a VCC-reference signal of the second driver circuitry; and
a level-down circuitry converting the VCC-reference signal of the second driver circuitry into the GND-reference signal of the second driver circuitry;
a gate of a second power transistor is connect with the drains of the third transistor and the fourth transistor; and
the first power transistor and the second power transistor configure a complementary MOSFET.

4. The gate driver circuitry according to claim 3, wherein:
a positive-side power supply potential applied to the gate of the first transistor is an electric potential equal to or lower than a ground potential applied to the gate of the second transistor; and
a positive-side power supply potential applied to the gate of the third transistor is an electric potential equal to or lower than a ground potential applied to the gate of the fourth transistor.

5. The gate driver circuitry according to claim 3, wherein:
the first power transistor is an n-type power transistor;
the second power transistor is a p-type power transistor; and
a positive-side power supply potential applied to a gate of the first power transistor is an electric potential equal to or lower than a ground potential applied to a gate of the second power transistor.

6. The gate driver circuitry according to claim 4, wherein:
the first power transistor is an n-type power transistor;
the second power transistor is a p-type power transistor; and
a positive-side power supply potential applied to a gate of the first power transistor is an electric potential equal to or lower than a ground potential applied to a gate of the second power transistor.

7. The gate driver circuitry according to claim 3, wherein
the first driver circuitry further comprises:
a first level shift circuitry connected between the gate of the second transistor and the level-down circuitry, converting, regarding a voltage applied to the gate of the second transistor, a positive-side power supply potential from a level regarding which a ground potential of the second power transistor is set as a reference to a level regarding which a positive-side power supply potential of the first power transistor is set as a reference, and outputting the voltage to the level-down circuitry; and
a second level shift circuitry connected between the level-up circuitry and the gate of the second transistor, converting, regarding a voltage output from the level-up circuitry, a positive-side power supply potential from a level regarding which the positive-side power supply potential of the first power transistor is set as a reference to a level regarding which the ground potential of the second power transistor is set as a reference, and outputting the voltage to a gate of a complementary MOSFET which outputs a signal that is applied to the gate of the second transistor.

8. The gate driver circuitry according to claim 3, wherein
the second driver circuitry further comprises:
a third level shift circuitry connected between the level-down circuitry and the gate of the third transistor, converting, regarding a voltage output from the level-down circuitry, a ground potential from a level regarding which a positive-side power supply potential of the first power transistor is set as a reference to a level regarding which a ground potential of the second power transistor is set as a reference, and outputting the voltage to a gate of a complementary MOSFET which outputs a signal that is applied to the gate of the third transistor; and
a fourth level shift circuitry connected between the gate of the third transistor and the level-up circuitry, converting, regarding a voltage applied to the gate of the third transistor, a ground potential from a level regarding which a positive-side power supply potential of the second power transistor is set as a reference to a level regarding which a ground potential of the first power transistor is set as a reference, and outputting the voltage to the level-up circuitry.

9. The gate driver circuitry according to claim 6, wherein
the first driver circuitry further comprises:
a first level shift circuitry connected between the gate of the second transistor and the level-down circuitry, converting, regarding a voltage applied to the gate of the second transistor, a positive-side power supply potential from a level regarding which a ground potential of the second power transistor is set as a reference to a level regarding which a positive-side power supply potential of the first power transistor is set as a reference, and outputting the voltage to the level-down circuitry; and
a second level shift circuitry connected between the level-up circuitry and the gate of the second transistor, converting, regarding a voltage output from the level-up circuitry, a positive-side power supply potential from a level regarding which the positive-side power supply potential of the first power transistor is set as a reference to a level regarding which the ground potential of the second power transistor is set as a reference, and outputting the voltage to a gate of a complementary MOSFET which outputs a signal that is applied to the gate of the second transistor.

10. The gate driver circuitry according to claim 6, wherein
the second driver circuitry further comprises:
a third level shift circuitry connected between the level-down circuitry and the gate of the third transistor, converting, regarding a voltage output from the level-down circuitry, a ground potential from a level regarding which a positive-side power supply potential of the first power transistor is set as a reference to a level regarding which a ground potential of the second power transistor is set as a reference, and outputting the voltage to a gate of a complementary MOSFET which outputs a signal that is applied to the gate of the third transistor; and
a fourth level shift circuitry connected between the gate of the third transistor and the level-up circuitry, converting, regarding a voltage applied to the gate of the third transistor, a ground potential from a level regarding which a positive-side power supply potential of the second power transistor is set as a reference to a level regarding which a ground potential of the first power transistor is set as a reference, and outputting the voltage to the level-up circuitry.

11. The gate driver circuitry according to claim 9, wherein
the second driver circuitry further comprises:
a third level shift circuitry connected between the level-down circuitry and the gate of the third transistor, converting, regarding a voltage output from the level-down circuitry, a ground potential from a level regarding which the positive-side power supply potential of the first power transistor is set as a reference to a level regarding which the ground potential of the second power transistor is set as a reference, and outputting the voltage to a gate of a complementary MOSFET which outputs a signal that is applied to the gate of the third transistor; and
a fourth level shift circuitry connected between the gate of the third transistor and the level-up circuitry, converting, regarding a voltage applied to the gate of the third transistor, a ground potential from a level regarding which the positive-side power supply potential of the second power transistor is set as a reference to a level regarding which the ground potential of the first power transistor is set as a reference, and outputting the voltage to the level-up circuitry.
